(19) United States
(12) Patent Application Publication
(10) Pub. No.: US 2026/0082848 A1
(43) Pub. Date: Mar. 19, 2026

(54) HIGH TEMPERATURE ANNEALING OF SEMICONDUCTOR SUBSTRATES

(71) Applicant: Yield Engineering Systems, Inc., Fremont, CA (US)

(72) Inventors: Christopher Lane, Los Gatos, CA (US); Tapani Laaksonen, Fremont, CA (US); Alan Lee Stone, Bloomington, CA (US); Vladimir Kudriavtsev, Palo Alto, CA (US); M Ziaul Karim, San Jose, CA (US)

(21) Appl. No.: 19/382,485

(22) Filed: Nov. 7, 2025

Related U.S. Application Data
(63) Continuation-in-part of application No. 18/887,341, filed on Sep. 17, 2024.

(51) Int. Cl. H01L 21/67; H01L 21/687

(52) U.S. Cl. CPC H10P 72/0434; H10P 72/7611

(57) ABSTRACT

An annealing system for semiconductor substrates includes a process chamber with multiple angularly arranged zones. A carrier rotates substrates between a first and second zone. An induction heater in the first zone heats the substrate, while a heat shield above the substrate, composed of thermally insulating material, controls temperature. The shield has a crown and rim, with one or more resistive heaters to adjust the rim's temperature relative to the temperature of the crown for improving uniformity of substrate temperature.

### CROSS-REFERENCE TO RELATED APPLICATIONS

This application is a continuation-in-part (CIP) application of U.S. application Ser. No. 18/887,341 filed Sep. 17, 2024, the disclosure of which is incorporated by reference herein in its entirety.

### TECHNICAL FIELD

The present disclosure relates to systems and methods for annealing semiconductor substrates at high temperatures, for example, using induction heating.

### BACKGROUND

Annealing of semiconductor substrates is a thermal process used to alter the physical and electrical properties of materials. During semiconductor processing, annealing of substrates may be carried out for many reasons, such as, for example, defect reduction, dopant activation, stress relief, oxide layer formation, grain growth, improvement of interfacial properties, repairing damage to the crystal lattice caused by another process (e.g., ion implantation, etc.). Annealing is typically done through a controlled thermal process, which involves heating the material to an annealing temperature for a defined soak period, followed by controlled cooling. In high-volume manufacturing (HVM), a batch process is typically used to anneal multiple substrates at the same time.

### SUMMARY

Several implementations of devices and methods for annealing semiconductor substrates are disclosed. It is to be understood that both the foregoing general description and the following detailed description are exemplary and explanatory only. As such, the scope of the disclosure is not limited solely to the disclosed implementations. Instead, it is intended to cover such alternatives, modifications and equivalents within the spirit and scope of the disclosed implementations. Persons skilled in the art would understand how various changes, substitutions and alterations can be made to the disclosed implementations without departing from the spirit and scope of the disclosure.

An annealing system designed for doped semiconductor substrates is described, featuring a process chamber with a central axis and one or more process zones. When multiple zones are included, they may be positioned at angular intervals around the central axis, with at least a first and second process zone identified. A carrier within the chamber may support the substrate during the annealing process. The system also incorporates one or more induction heaters, strategically placed within the process chamber to heat the substrate. These heaters may be located above, below, or both above and below the carrier to directly expose and heat the surface of the substrate on the carrier. Additionally, the process chamber may be equipped with a removable cap that includes a heat shield. This heat shield can include at least one layer of thermally insulating material and is designed to protect the walls of the process chamber from radiant heat emanating from the substrate. The cap may be inserted into the process chamber through an opening in the wall of the process chamber and removed from the process chamber though the opening. When used, the cap may be inserted into the process chamber and securely attached so that the heat shield is positioned over the substrate located in the first process zone. This configuration allows for precise and controlled heating during the annealing process, protecting the walls (and other components of the process chamber) from excessive heat while facilitating desired temperature reach and regulation of the substrate.

In one implementation, an annealing system for a semiconductor substrate is disclosed, featuring a process chamber with a central axis and multiple process zones arranged angularly around it. These zones may include a first process zone and a second process zone. A carrier, positioned within the chamber, may be designed to support the substrate and rotate about the central axis, facilitating its movement from the first process zone to the second. An induction heater may be located in the first process zone beneath the carrier and may be configured to heat the substrate while it is in this zone. Above the substrate, a heat shield composed of at least one layer of thermally insulating material may be positioned. This heat shield may include a crown portion and a rim portion extending around the crown's periphery. To enable temperature control, one or more resistive heaters may be coupled to the heat shield. In some implementations, a first resistive heater may be coupled to the crown portion, while a second resistive heater may be attached to the rim portion, allowing for adjustments to the rim's temperature relative to the crown.

In another implementation, an annealing system for semiconductor substrates that includes a process chamber containing both a first and a second carrier is disclosed. The first carrier may feature a cavity designed to support a substrate, exposing its bottom surface through the cavity. Similarly, the second carrier may include a cavity configured to support a second substrate, also exposing its bottom surface through the cavity. Positioned between the carriers may be a liquid-cooled induction heater, located below the first carrier and above the second. This arrangement places the exposed bottom surface of the first substrate above the induction heater and the top surface of the second substrate below it. To regulate thermal conditions, a first heat shield, comprising at least one layer of thermally insulating material, may be placed above the first carrier. Similarly, a second heat shield, also made of thermally insulating material, may be positioned below the second carrier and the exposed bottom surface of the second substrate.

In another implementation, an annealing system for a semiconductor substrate is disclosed. The annealing system may include a process chamber having a central axis and multiple process zones angularly spaced apart from each other about the central axis. The multiple process zones may include a first process zone and a second process zone. A carrier may be positioned in the process chamber. The carrier may be configured to support the substrate and rotate about the central axis to transport the substrate from the first process zone to the second process zone. An induction heater may be located in the first processing zone of the process chamber. The induction heater may be positioned below the carrier and configured to heat the substrate positioned in the first process zone. A heat shield including at least one layer of a thermally insulating material may be disposed above the substrate positioned in the first process zone. The heat shield may include a crown portion and a rim portion extending around a periphery of the crown portion. A first resistive heater may be coupled to the crown portion and a second resistive heater may be coupled to the rim portion to vary a temperature of the rim portion relative to the crown portion.

In yet another implementation, an annealing system for semiconductor substrates is disclosed. The annealing system may include a process chamber, a first carrier and a second positioned in the process chamber. The first carrier may include a first cavity configured to support a first substrate such that a bottom surface of the first substrate is exposed through the first cavity, and the second carrier may include a second cavity configured to support a second substrate such that a bottom surface of the second substrate is exposed through the second cavity. A liquid-cooled induction heater may be disposed below the first carrier and above the second carrier such that the bottom surface of the first substrate that is exposed through the first cavity is positioned above the induction heater and a top surface of the second substrate is positioned below the induction heater. A first heat shield including at least one layer of a thermally insulating material may be disposed above the first carrier such that a top surface of the first substrate is positioned below the first heat shield, and a second heat shield including at least one layer of a thermally insulating material may be disposed below the second carrier such that the bottom surface of the second substrate exposed through the second cavity is positioned above the second heat shield.

### BRIEF DESCRIPTION OF THE DRAWINGS

The accompanying drawings, which are incorporated in and constitute a part of this disclosure, illustrate exemplary implementations and, together with the description, are used to explain the disclosed principles. In these drawings, where appropriate, reference numerals illustrating like structures, components, materials, and/or elements in different figures are labeled similarly. It should be noted that the figures only depict some exemplary implementations of the current disclosure and there can be many variations. The figures illustrate implementations used to describe some features of the current disclosure. It is understood that various combinations of the structures, components, and/or elements, other than those specifically shown, are contemplated and are within the scope of the present disclosure. Specifically, the scope of the current disclosure is defined by the claims and not by the specific implementations illustrated in the figures.

For simplicity and clarity of illustration, the figures depict the general structure of the various described implementations. Details of well-known components or features may be omitted to avoid obscuring other features, since these omitted features are well-known to those of ordinary skill in the art. Further, elements in the figures are not necessarily drawn to scale. The dimensions of some features may be exaggerated relative to other features to improve understanding of the exemplary implementations. One skilled in the art would appreciate that the features in the figures are not necessarily drawn to scale and, unless indicated otherwise, should not be viewed as representing proportional relationships between features in a figure. Additionally, even if it is not specifically mentioned, aspects described with reference to one implementation or figure may also be applicable to, and may be used with, other implementations or figures.

FIG. 1 is a schematic illustration of a processing chamber of an annealing apparatus, consistent with some implementations of the current disclosure;

FIG. 2 is a schematic illustration of an exemplary processing zone of the chamber of FIG. 1 with an exemplary drop-in module, consistent with some implementations of the current disclosure;

FIGS. 3A-3C are schematic illustrations of some exemplary drop-in modules in the processing chamber of FIG. 1, consistent with some implementations of the current disclosure;

FIG. 4 is a schematic illustration of a port of the chamber of FIG. 1, consistent with some implementations of the current disclosure;

FIG. 5 is a flow chart of an exemplary method of thermal processing of a semiconductor substrate;

FIG. 6 is a schematic illustration of active temperature control of the heat shield in the processing zone of the chamber of FIG. 1, consistent with some implementations of the current disclosure;

FIG. 7 is a schematic illustration of a double-side heating mechanism in the processing zone of the chamber of FIG. 1, consistent with some implementations of the current disclosure;

FIG. 8 is a schematic illustration of a stacked heating mechanism in the processing zone of the chamber of FIG. 1, consistent with some implementations of the current disclosure; and

FIGS. 9A and 9B are schematic illustrations of a heating mechanism for horizontally spaced substrates in the processing zone of the chamber of FIG. 1, consistent with some implementations of the current disclosure.

### DETAILED DESCRIPTION

All relative terms such as “about,” “substantially,” “approximately,” etc., indicate a possible variation of +10% (unless noted otherwise or another variation is specified). For example, a temperature disclosed as being about 1000° C. may vary in temperature from 900° C. to 1000° C. unless specified otherwise. Similarly, a temperature within a range of about 1000-1500° C. can be any temperature between (1000-10%) and (1500+10%). In some cases, the specification also provides context to some of the relative terms used. For example, a temperature described as being substantially uniform may deviate slightly (e.g., 10% variation in temperature at various locations, etc.) in temperature. Further, a range described as varying from, or between, 1000 to 1500 (1000-1500), includes the endpoints (i.e., 1000 and 1500). Such deviations can arise from factors such as measurement inaccuracies, inherent variability in the system, or external influences that cause slight fluctuations in a measured parameter. In many cases, the variation is so small that it does not significantly impact the overall behavior or outcome, but it acknowledges that a perfectly constant value is difficult to achieve in practice. Thus, in this disclosure, relative terms are used to allow for some degree of variation resulting from practical, real-world, reasons.

Unless otherwise defined, all terms of art, notations, and other scientific terms or terminology used herein have the same meaning as is commonly understood by one of ordinary skill in the art to which this disclosure belongs. Some of the components, structures, and/or processes described or referenced herein are well understood and commonly employed using conventional methodology by those skilled in the art. Therefore, these components, structures, and processes will not be described in detail. All patents, applications, published applications and other publications referred to herein as being incorporated by reference are incorporated by reference in their entirety. If a definition or description set forth in this disclosure is contrary to, or otherwise inconsistent with, a definition and/or description in these references, the definition and/or description set forth in this disclosure controls over those in the references that are incorporated by reference. None of the references described or referenced herein is admitted as prior art to the current disclosure.

As used herein, unless specifically stated otherwise, the term “or” encompasses all possible combinations, except where infeasible. For example, if it is stated that a component (method, etc.) can comprise A or B, then, unless specifically stated otherwise or infeasible, the component can comprise A, or B, or A and B. As a second example, if it is stated that a component can comprise A, B, or C, then, unless specifically stated otherwise or infeasible, the component can comprise A, or B, or C, or A and B, or A and C, or B and C, or A and B and C.

The term substrate refers to the base material on which semiconductor or photonic devices or circuits are fabricated. In the discussion below, the term “substrate” is used broadly to refer to any component having a relatively flat surface upon which structures of semiconductor devices or photonic devices may be created. For example, as used herein, a substrate includes a plate, a panel (e.g., a glass panel used in LCD or semiconductor manufacturing, photomask manufacturing, etc.), a semiconductor wafer (e.g., a silicon wafer used to fabricate IC devices), a wafer with multiple IC devices formed thereon, a single IC device, a part (e.g., ceramic, organic, metallic, etc.) with one or more coatings formed or disposed thereon, etc. In some implementations, the substrate may be a wafer (for example, having a diameter of 100 mm, 150 mm, 200 mm, or larger). In some implementations, the wafer (i.e., substrates) may be made of crystalline silicon carbide or other wide bandgap semiconductors (GaN, graphene, diamond) that require high temperature post-implantation or post-etch annealing to repair crystal defects, activate dopants or enhance electrical properties.

Generally, tools (e.g., ovens, etc.) used to anneal silicon carbide substrates in high-volume manufacturing can employ a batch processing method, where a large boat of substrates (e.g., containing 50, 75, or even 150 wafers) is slowly ramped up to the annealing temperature and then cooled down. The maximum substrate temperature than can be achieved during annealing in such a process is typically limited by the type and placement of heaters, often remaining significantly below 1800° C. For optimal annealing of SiC doped wafers at a faster rate, temperatures between 1750-2200° C. are desired, necessitating heaters with temperatures a few hundred degrees higher. Consequently, annealing silicon carbide substrates using conventional annealing tools is time-consuming, with some systems taking several hours (e.g., up to 10 hours) to ramp up and cool down. Fast cool-down from annealing temperature (e.g., to freeze properties) is also challenging to achieve using conventional annealing tools. This limitation hinders the ability to anneal crystalline silicon carbide wafer efficiently, especially in high volume manufacturing (HVM) environments. Additionally, such conventional annealing methods may result in uneven heating and cooling across substrates, leading to variations in annealing quality and uniformity. Moreover, in this temperature range heater reliability and variation of heater surface properties (e.g., exfoliation and oxidation) present a significant problem in high volume manufacturing. Annealing tools and methods of the current disclosure may alleviate at least some of the above-described deficiencies.

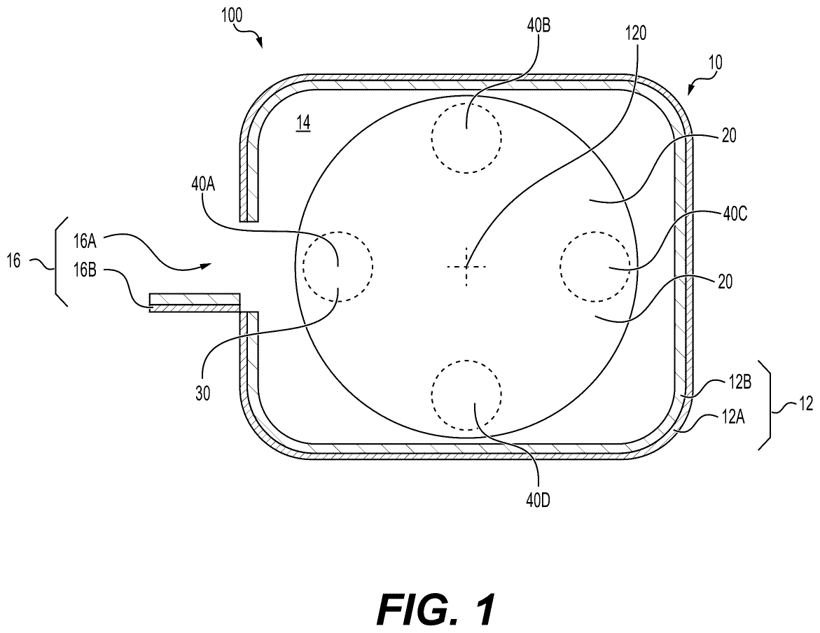

FIG. 1 is a schematic representation of the top view of an exemplary apparatus (or tool) 100 that may be used to anneal a semiconductor substrate 10 consistent with some implementations of the current disclosure. Although substrates of any semiconductor material (e.g., silicon, gallium arsenide, etc.) may be annealed in apparatus 100, in the discussion below annealing of a silicon carbide substrate will be described. As will be recognized by persons skilled in the art, annealing silicon carbide substrates presents several unique challenges compared to other semiconductor substrates like silicon or gallium arsenide or gallium nitrate. These challenges arise primarily due to the physical and chemical properties of silicon carbide requiring much higher annealing temperatures (typically between about 1500-2200° C.) as compared to other semiconductor materials (e.g., between about 600-1100° C. for silicon). Therefore, the heaters of apparatus 100 that heat the silicon carbide substrates to annealing temperature should be capable of heating the substrates to the desired high annealing temperature, and the components of apparatus 100 should be able to withstand these high temperatures and to do that reliably during the production cycles.

Apparatus 100 includes a process chamber 10 with a chamber wall 12 that bounds a chamber volume 14. In some implementations, chamber wall 12 may have a multi-layered structure with a metal layer 12A on the outside and an insulation layer 12B on the inside bounding the chamber volume 14. Metal layer 12A may me made of any suitable metal (e.g., Inconel), and insulation layer 12B may be made of any suitable thermally insulating material(s). In some implementations, insulation layer 12B may itself include multiple layers (e.g., of different insulating materials) coupled together. One or more substrates 10 are configured to be positioned in chamber volume 14 for processing (e.g., annealing). The process conditions (e.g., temperature, type of gas, pressure of the gas, etc.) in the chamber volume 14 may be controlled to support the annealing process. In some implementations, chamber 10 may include common controls for pressure, suction, and gas input into volume 14. Chamber 10 may also include a common insulation padding and cooling (e.g., liquid cooling) for volume 14.

Chamber 10 may include a loading/unloading port 16 through which one or more substrates (e.g., substrate 30) may be inserted into, and removed from, the chamber volume 14. Port 16 may include an opening 16A on the chamber wall 12 configured to be opened and closed by, for example, a valve or a door 16B. After insertion of the substrates, opening 16A may be closed by the door 16B to isolate the chamber volume 14 from the external environment. In general, any number of substrates may be simultaneously processed in chamber 10. In the discussion below, the processing of a single substrate 30 will be discussed. However, this is not a requirement, and any number of substrates may be simultaneously processed in chamber 10.

Chamber volume 14 may include a carrier 20 configured to support one or more substrates (e.g., substrate 30) within chamber 10. In some implementations, as illustrated in FIG. 1, carrier 20 may be a carousel configured to rotate about a vertical axis 120 to position the substrate 30 in different zones 40A, 40B, 40C, etc. within chamber 10. In some implementations, carrier 20 may additionally be configured to move along (e.g., up and down) the vertical axis 120. A zone refers to an area (or region) within the chamber volume 14 where specific processes are designed to occur. The different zones may be angularly spaced apart (by any angle) from one another. These zones may include a loading/unloading zone 40A where substrate 30 is inserted into the chamber 10 for processing and removed from the chamber 10 after processing. Substrate 30 may be inserted into chamber 10 and positioned in the loading/unloading zone 40A of carrier 20 in any manner. In some implementations (for example, in a high-volume manufacturing environment), an automated robotic arm of a substrate handler may retrieve a substrate from a cassette and position it within the chamber 10 through port 16. Meanwhile, in some implementations (e.g., in a lab environment), the substrate may be manually inserted and deposited within the chamber 10.

With continued reference to FIG. 1, the zones of chamber 10 may also include one or more processing zones (e.g., 40B, 40C, 40D) circumferentially spaced apart from each other. In some implementations, the substrate 10 may be subjected to different process conditions (e.g., heating, cooling, etc.) at these different processing zones. In some implementations, the various processing zones (e.g., 40B, 40C, 40D) may be designed to heat or cool the substrate in a progressive manner. For example, if the substrate 30 needs to be heated up to 2000° C. for annealing, the first zone 40B may heat the substrate 30 to 1200° C., and then rotate the carrier 20 (about axis 120) to move the substrate 30 to the second zone 40C where it is heated to 2200° C. After being held at the annealing temperature for the desired time, the carrier 20 may again be rotated to move the substrate to the third zone 40D where it is cooled from 2200° C. to a lower temperature before it is rotated to zone 40A for removal from the chamber 10 via port 16. Some implementations may include multiple cooling zones using which the hot substrate may be progressively cooled. In some implementations, heaters may be configured to heat different parts of substrate, for the combined volumetric activation net effect.

Although the previous example describes processing a single substrate in a zone at a time, chamber 10 can handle multiple substrates simultaneously. For instance, while a first substrate is heated in processing zone 40B (e.g., to 1200° C.), a second substrate can be loaded in zone 40A. As the first substrate moves to zone 40C for further heating (e.g., to 2200° C.), the second substrate moves to zone 40B, and a third substrate is loaded into zone 40A. This staggered movement allows multiple substrates to be processed concurrently. Additionally, multiple substrates can be processed simultaneously within each processing zone. For example, multiple substrates (e.g., 2, 3, 4, etc.) may be loaded in zone 40A and rotated through the different zones (40B, 40C, etc.) to progressively process the multiple substrates simultaneously in each zone.

In the exemplary implementation shown in FIG. 1, chamber 10 features four zones (40A-40D) spaced 90 degrees apart. This is only exemplary. Generally, chamber 10 can include any number of zones (e.g., 1-10). Typically, the number of zones is limited geometrically by the diameter of the wafer and of the chamber outer diameter. For example, some implementations may have 3 zones (one loading/unloading zone and two processing zones). These zones may be equally spaced apart in some implementations. In general, the substrate, after loading, rotates through the several processing zones before returning for unloading. The substrate may be progressively heated to the desired temperature in the initial zones and then cooled in the final zones before removal. In some implementations, the chamber 10 may include just a single zone (e.g. in its most compact configuration) that serves as the loading zone, heating zone, and the cooling zone.

A rotating carrier 20 for moving the substrate 30 between different processing zones is just one example. In some implementations, chamber 10 may have a single zone. In such cases, the substrate 30 is inserted and placed on carrier 20 (e.g., via port 16) at one location where the processing (e.g., annealing) occurs. After heating and cooling at the same location, the substrate is removed from the chamber. A water cooled coil of an induction heater assists in rapid cooldown of the substrate. This disclosure applies to both single-zone and multi-zone chambers.

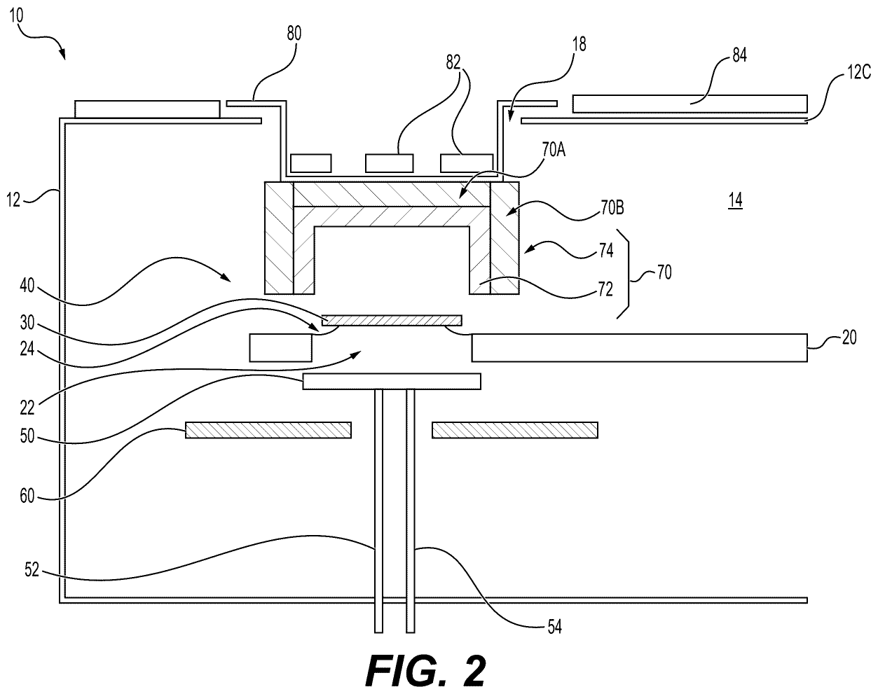

FIG. 2 is a schematic illustration of an exemplary region 40 (e.g., a processing zone) within chamber 10 where the processing of substrate 30 is carried out. In some implementations (e.g., in multi-zone implementations), region 40 may correspond to a processing zone (40B, 40C, etc.) to which the carrier 20 rotates the substrate 30 in FIG. 1, while in other implementations (e.g., in single-zone implementations), it may indicate the location where the substrate 30 is inserted and placed on the carrier 20.

Carrier 20 may feature a cavity (or through hole) 22, bordered by standoffs 24 that project inward into the cavity. These standoffs can include various support elements such as pillars, posts, mounts, elevations, risers, pedestals, pins, or studs. They help support the substrate 30 on carrier 20, positioning it above the cavity 22, with one side (e.g., the bottom surface) of the substrate 30 vertically spaced apart from the top surface of the carrier 20.

In some implementations, the shape of the cavity 22 may correspond to (or be similar to) the shape of the substrate 30, while the size of the cavity 22 may be larger than that of the substrate 30. For example, if the substrate 30 is a circular 200 mm diameter wafer, the cavity 22 may be a substantially circular hole with a diameter greater than 200 mm (e.g., about 250-350 mm, etc.). Generally, any number (e.g., 3-10) and configuration of standoffs 24 may be provided around the cavity 22. In some implementations, the standoffs 24 may support the substrate 30 such that a vertical gap of about 0.2-10 mm (or 0.5-2 mm in some implementations) is formed between the bottom surface of the substrate 30 and the top surface of the carrier 20.

An induction heater 50 can be positioned beneath the cavity 22, on the side of the carrier 20 opposite the substrate 30. This induction heater 50 is utilized for heating the substrate 30 supported on the standoffs 24 of carrier 20 through the cavity 22. When alternating current flows through heater coil 50, it produces an alternating magnetic field that induces eddy currents in doped substrate 30, causing it to heat up due to resistive losses. In general, any type of induction heater (high-frequency, medium-frequency, low-frequency, etc.) may be used. In some implementations, induction heater 50 may be a high-frequency induction heater configured to rapidly heat substrate 30. Substrate, such as doped crystalline Silicon Carbide will heat up because of doping. In contrast, an undoped substrate has minimal (or no) electrical conductivity and therefore will not get heated by the induction heater 50.

The difference in how doped and undoped semiconductor substrates 30 respond to induction heating lies in their electrical conductivity. A doped semiconductor contains impurities, known as dopants, that introduce free charge carriers-either electrons in the case of N-type doping or holes in the case of P-type doping. These free carriers increase the electrical conductivity of the material. When a doped semiconductor is placed in the alternating magnetic field generated by induction heater 50, the free charge carriers move in response to the changing field, creating eddy currents within the material. These eddy currents, in turn, generate heat due to resistive (or Joule) heating, allowing the doped semiconductor substrate to be efficiently heated. In contrast, an undoped, or intrinsic, semiconductor lacks significant free charge carriers at room temperature, resulting in much lower electrical conductivity. As a result, when subjected to the alternating magnetic field of induction heater 50, the undoped semiconductor substrate is unable to sustain the necessary eddy currents to generate heat. The absence of sufficient charge carriers means that the material cannot absorb energy from the magnetic field, and therefore, remains unaffected by the induction heating process. This fundamental difference in conductivity between doped and undoped semiconductors is why doped substrates are processed in chamber 10 using induction heater 50.

It should be noted that, although an implementation where heater 50 is positioned below the substrate is described, in some implementations, (alternatively or additionally) an induction heater may be positioned above the substrate. In some implementations, induction heaters may be positioned above and below the substrate, while in some implementations, an induction heater may only be positioned on one side (above or below) the substrate. In general, the induction heater(s) can be strategically placed anywhere within the processing zone of the process chamber to efficiently heat the substrate. It may be located either beneath the carrier, above the carrier, or both above and below, depending on the specific heating requirements. The induction heater is designed to provide targeted thermal energy to the substrate situated within the processing zone, ensuring uniform and precise heating necessary for optimal processing conditions. This flexible positioning allows for enhanced control over the heating process, improving both the efficiency and quality of the substrate treatment. It is also contemplated that, in some implementations, one or more induction heaters may be (additionally or alternatively) positioned on the sides of (e.g., around) the substrate.

In some implementations, the induction heater 50 may be a liquid-cooled pancake-style coil induction heater. For instance, the coil may be flat and circular, resembling a pancake, and constructed from an electrically conductive material such as copper or other suitable metals. Coil can also be cylindrical or combination of cylindrical and pancake or multiple coils can be used driving at various frequencies. The coil can be housed in a system that circulates a liquid coolant (such as, for example, water) around it for cooling. This system may include tubing wound around the coil or a jacket encasing the coil. In some implementations, induction heater 50 includes liquid-cooled copper conductors made of tubing that is formed into the shape of a coil. Coil shape can be optimized for maximum heating efficiency and uniformity, can be cylindrical, pancake or combination of both, can include multiple coils driving at different frequencies and different coils can be used at different stations. These induction heating coils do not themselves get hot as coolant flows through them. The liquid cooling system disperses the heat generated in the coil, preventing overheating, and maintaining the efficiency and safety of the induction heating process.

The induction heater 50 may be vertically spaced apart from the bottom surface of the carrier 20. The vertical gap between the bottom surface of the carrier 20 and the top surface of the induction heater 50 may be between about 0.5-10 (or about 1-5 mm). Generally, the size (e.g., diameter) of the induction heater 50 may be greater than the size (e.g., diameter) of the substrate 30. For example, if the substrate has a diameter of about 200 mm, the diameter of the induction heater 50 may be, for example, about 280 mm. In some implementations, the size (e.g., diameter) of the induction heater 50 may be greater than the size of the cavity 22 on the carrier 20. Electrical cables 52 connected to a power supply unit (not shown) directs current to the induction heater 50, and fluid conduits 54 circulate a liquid coolant (e.g., water) to the induction heater 50. In some implementations, a controller of apparatus 100 may control the operation (e.g., activation, deactivation, adjust current and other parameters, etc.) of induction heater 50.

A radiative heat shield 60 may be positioned below the induction heater 50 to reduce heat loss to the chamber walls 12 and the environment below the shield 60 via radiation. Heat shield 60 may be made of any suitable material. Typically, the materials used in the heat shield 60 may depend on the application (e.g., the heater power, etc.). For example, if the induction heater 50 is used to heat the substrate to high temperatures (such as, for example, 2000° C.), the heater power may be high, and the heat shield may be made of materials that can support such heat radiation. In general, materials such as, for example, refractory metals (e.g., tungsten, molybdenum, tantalum, etc.), ceramic materials, composite materials (carbon-carbon composite, etc.), graphite, refractory concrete, etc. may be used in heat shield 60. While heat shield 60 is depicted as a flat plate, this is merely an example. Generally, heat shield 60 can take any appropriate shape to improve heating uniformity and to reduce heat loss via radiation beneath heater 50. For instance, in some implementations, heat shield 60 may have a cup-like (concave side up) or hat-like shape (similar to heat shield 70 described below), with a portion (e.g., a rim) of the heat shield extending around the sides of heater 50 to minimize radiative heat loss through the sides.

When substrate 30 is heated to high temperatures by induction heater 50, it radiates heat (like a heater). Based on Stefan-Boltzmann law, the heat radiated by the heated substrate 30 can be estimated as σ·A·T\hat{ }4, where σ is Stefan-Boltzmann constant, A is surface area of the radiating substrate, and T is temperature in Kelvin. When substrate 30 is heated to high temperatures (e.g., temperatures above 1400° C.), it becomes a heater that emits tens of kilowatts of heat. For example, assuming perfect black body radiation (with an emissivity=1), a 200 mm diameter substrate 30 heated to 2200° C. emits about 47 KW of heat creating a furnace-like environment in chamber 10. This large amount of heat has to be removed from chamber 10 without causing thermally-induced damage (such as melting of chamber walls 12) to the components of the chamber 10. In implementations of the current disclosure, heat shields 70 and 60 and other components of chamber 10 are designed to contain heat loss from such a powerful heat radiator without causing damage to chamber components, and to remove remaining heat for net zero balance.

To minimize heat loss from the heated substrate 30 through radiation, a radiative heat shield 70 is positioned above the substrate 30. In some designs, the heat shield 70 may have a hat-like shape with a rim portion 70B extending downwards from, and around, a crown portion 70A. The shape of the crown portion 70A may correspond to the shape of the substrate 30. For instance, if the substrate 30 is circular, the crown portion 70A may also be substantially circular. Similarly, if the substrate is square, the crown portion 70A may have a substantially square shape. The crown portion 70A is larger than the substrate 30 (and the cavity 22), ensuring that the opening defined by the bottom edge of the rim portion 70B is greater than the size of the substrate 30 (and the cavity 22).

In some implementations, when the substrate 30 is circular and has a diameter of 200 mm, the crown portion 70A may also be substantially circular and have a diameter between about 220-240 mm such that a horizontal gap of about 10-20 mm is formed between the outer edge of the substrate 30 and the inner edge of the heat shield rim portion 70B. The heat shield 70 is positioned so that the rim portion 70B encircles the substrate 30, with the bottom edge of the rim portion 70B positioned close to the top surface of the carrier 20. This positioning places the substrate 30 within the volume enclosed by the rim portion 70B and the crown portion 70A of the heat shield 70 (or the heat shield volume). In some implementations, the heat shield 70 may be positioned over the substrate 30 such that there is a vertical gap of between about 0.5-20 mm (or 1-10 mm) between the bottom edge of the rim portion 70B and the top surface of the carrier 20. In some implementations, the heat shield 70 may be positioned over the substrate 30 such that the bottom edge of the rim portion 70B contacts (e.g., rests on) the top surface of the carrier 20. Positioning the substrate 30 within the heat shield volume minimizes heat loss from the substrate 30 to the atmosphere (of chamber volume 14) outside the heat shield volume and the resultant heating of chamber walls 12 (and other components).

Like heat shield 60, heat shield 70 may generally be made of any suitable shield material (refractory metals such as, for example, tungsten, molybdenum, tantalum, etc., ceramic materials, composite materials (carbon-carbon composite, etc.), high temperature ceramics (such as SiC, ZrC, h-BN, HfC, ZrO₂, Y-TZP, Al₂O₃, Y₂O₃), graphite, refractory concrete, etc.) that can withstand the high temperature environment in chamber 10, have good thermal shock resistance, and reduce radiative heat loss from the heated substrate 30. As discussed previously, the choice of the specific material may depend on the application. In some implementations, heat shield 70 may include multiple layers of insulation adapted to withstand the high temperatures resulting from the heated substrate. Each layer may be mounted on top of the other with appropriate bolts made of refractive metals to match the operating temperature range for each layer.

For example, in some implementations, as illustrated in FIG. 2, heat shield 70 may include a first (or inner) layer 72 facing the substrate 30 and a second (or outer) layer 74 facing the chamber walls 12. Generally, the first layer 72 may be made of a thermally insulating material that can withstand a higher temperature than the material of the second layer 74. In some implementations, first layer 72 may be made of graphite which can withstand high temperatures and has low out-of-plane thermal conductivity and high in-plane conductivity. The high in-plane conductivity improves temperature uniformity while the low out-of-plane conductivity reduces heat transfer in the out-of-plane direction. In some implementations, the second layer 74 may be made of lighter refractive ceramic material offering greater thermal resistance. First layer, if electrically conductive (metal) may not to be too close to the induction heater, to minimize its heating.

In general, the first layer 72 may be made of any of the above described shield materials and the second layer 74 may be made of another shield material. For example, in some implementations, the first layer 72 may be made of graphite and the second layer 74 may be made of a different shield material (e.g., a refractory metal (e.g., tungsten, molybdenum, tantalum, etc.), a ceramic material, a composite material, etc.). The thickness of the first and second layers 72, 74 may also be adapted to suit the application. The first and second layers 72, 74 may be attached together in any suitable manner (mechanical fasteners, high temperature adhesive/braze, etc.).

In certain configurations, the heat shield 70 can be designed as a modular unit that can be dropped into the chamber 10 through an opening 18 in the top wall 12C. For example, it could be affixed to the underside of a cap module (or cap 80), allowing insertion into the chamber 10 via the top wall opening 18. The cap 80 might be constructed from a high-temperature steel alloy (such as Inconel) in some scenarios. Cap 80 may feature coolant channels 82 designed to circulate a suitable liquid coolant (e.g., water). These channels 82 could be brazed onto the cap and connected to quick-disconnect flex connectors for coolant delivery and removal (e.g., cold water). During operation, the substrate 30 may emit tens of kilowatts of heat. The coolant flow rate through channel 82 may be sufficient to effectively dissipate this heat. In some implementations, a chiller with adequate cooling capacity may be connected to channel 82 to cool the coolant.

The cap 80 is shaped to cover and seal the opening 18 on the top wall 12C, so when it is inserted, the opening is effectively plugged and sealed. In some implementations, O-rings, gaskets, or other sealing members may assist with the sealing. The heat shield 70 can be attached to the underside of the cap 80 so that, when the cap 80 is inserted into the opening 18 and sealed against the top wall 12C, the bottom edge of the heat shield 70 either contacts or creates the desired gap with the top surface of the carrier 20.

In some implementations, the cap 80 can be inserted into the opening 18 (and sealed against the top wall 12C) in a way that allows the vertical position of the heat shield 70 above the substrate 30 to be adjusted. For instance, the cap 80 can be inserted and secured (e.g., to the top wall 12C) in a first position to create a first gap (e.g., 20 mm) between the bottom edge of the heat shield 70 and the top surface of the carrier 20. The cap 80 may also be inserted and secured in a second position to create a second gap (e.g., 5 mm) between the bottom edge of the heat shield 70 and the top surface of the carrier 20. In each of these positions (e.g., first and second), the cap 80 seals the opening 18 on the top wall 12C, ensuring that the desired process conditions (e.g., low pressure) are maintained within the chamber 10. The cap 80 may be secured to the top wall 12C at the different positions by any technique known in the art. Thus, in some implementations, the vertical spacing between the substrate 30 and the heat shield 70 may be variable.

The heat shield 70 may be attached to the underside of the cap 80 in any manner (mechanical fasteners, high temperature adhesive/braze, etc.). It is also contemplated that, in some implementations, the heat shield 70 and the cap 80 may be formed as a single unitary body (e.g., formed as a monolithic component of a refractory material). In some implementations, the cap 80 may be cooled using a suitable liquid coolant (e.g., water). For instance, the cap 80 could feature channels 82 through which a liquid coolant circulates, helping to dissipate the heat absorbed by the cap 80 during the operation of apparatus 10. The top wall 12C and/or other walls of the chamber 10 may also have channels 84 designed to circulate the coolant therethrough.

It should be noted that the heat shields 60, 70 discussed above with reference to FIG. 2 are only exemplary and many variations are possible. In general, the type of the heat shields 60 and 70 used depends on the desired processing conditions for the substrate 30. For example, referring to FIG. 1, in an exemplary implementation where processing zone 40B heats a substrate to 1400° C. and processing zone 40C heats the substrate to 2200° C., the heat emitted by the substrate at processing zone 40B will be substantially lower than at processing zone 40C. Therefore, a heat shield 70 designed to withstand higher temperatures (and block a greater radiative heat load) may be used in processing zone 40C compared to processing zone 40B. The number of layers (such as first layer 72 and second layer 74), their thickness, and/or the materials of the different layers can be chosen to match the radiative heat load in the two processing zones. In some implementations, caps 80 with different heat shields 70 coupled to their undersides may be inserted into the chamber wall openings 18 corresponding to the two processing zones 40B and 40C and positioned above the substrates positioned in these zones.

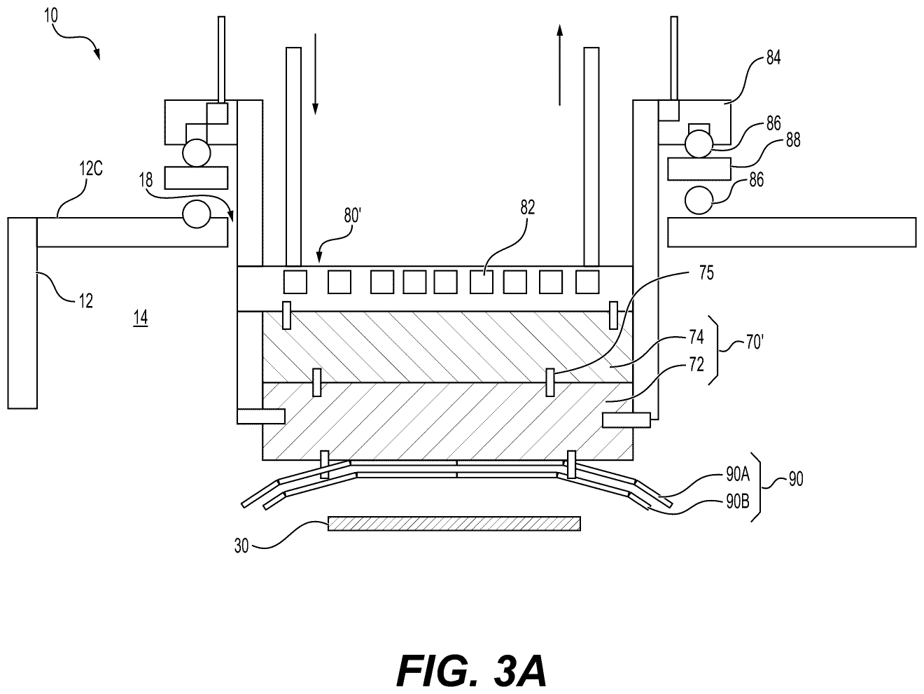

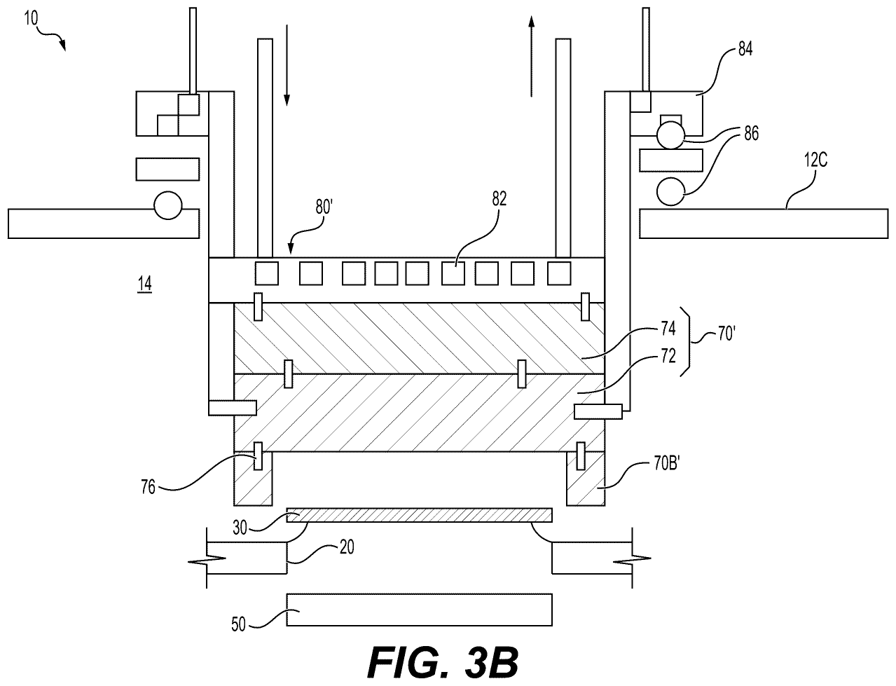

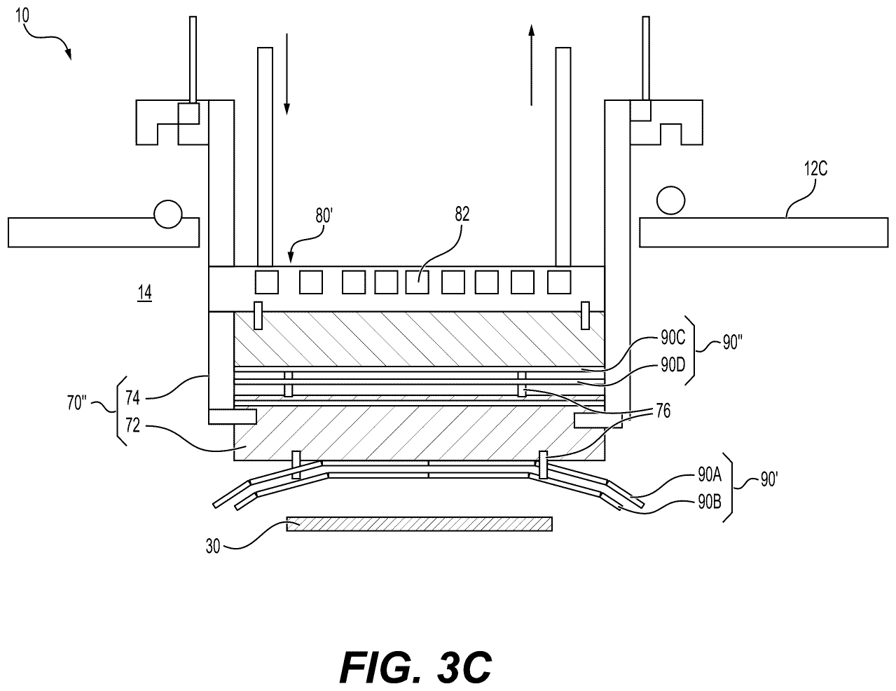

Alternatively, or additionally, the configuration of the heat shield 70 may differ across various processing zones. For example, FIG. 2 shows one version of heat shield 70, while FIG. 3A illustrates another version, 70′, attached to cap 80′ with mechanical fasteners 76. Like cap 80 in FIG. 2, cap 80′ may include coolant channels 82 and may be inserted through an opening 18 in the chamber's top wall 12C to adjust the vertical position of heat shield 70′ above the substrate 30. The substrate 30 is placed on a carrier and heated using an induction heater, as described in FIG. 2.

Cap 80′ includes a flange 84 that seals against the chamber top wall 12C. Similar to the FIG. 2 implementation, cap 80′ can be secured to allow adjustment of the vertical distance between the substrate 30's top surface and the heat shield 70's bottom surface. An optional spacer 88 between flange 84 (or cap 80′) and the chamber top wall 12C may further enable this vertical spacing adjustment. An O-ring 86 can assist in sealing the cap 80′ against the chamber's top wall 12C. The illustrated attachment mechanism for cap 80′ to the chamber 10 is exemplary.

Heat shield 70′ includes a first layer 72 (facing substrate 30) and a second layer 74 (facing chamber walls 12), connected by mechanical fasteners 76. The materials and thicknesses of these layers can be chosen based on the application, as discussed in FIG. 2. Heat shield 70′ may also include a multi-layer reflector assembly 90 attached to its underside. This assembly may have multiple reflectors (90A, 90B, etc.) made from materials like tantalum, molybdenum, tungsten, platinum, rhodium, and rhenium, designed to reflect radiant heat back to the substrate.

The reflectors are designed to optimize the reflection and concentration of radiant heat onto substrate 30, enhancing the efficiency and uniformity of its heating. In some implementations, the reflectors may be shaped like an elliptical dome with their concave side facing the substrate 30. Other curved shapes, such as parabolic, spherical, conical, or cylindrical, with their concave side facing the substrate, may also be used. The bottom surface of heat shield 70′ (e.g., the first layer 72's bottom surface) may be contoured to allow the multi-layer reflector assembly 90 to attach directly to it, ensuring no gap between mating surfaces. However, this is not a requirement, and in some implementations, air gaps may exist between the bottom surface of the first layer 72 and the reflector assembly 90. Typically, the reflectors 90A and 90B are larger than substrate 30 in diameter (or size). As discussed previously, the size (e.g., diameter) of the induction heater 50 (not shown) may be larger than the size of the substrate 30. In some implementations, the reflectors 90A, 90B may also exceed the diameter of the induction heater 50. For instance, when the diameter of substrate 30 is 200 mm, the heater diameter may range from about 250-300, and the diameter of the reflectors 90A, 90B may range from about 360-420 mm.

In some implementations, as shown in FIG. 3B, heat shield 70′ may include a guard ring 70B′ attached to the underside (e.g., the bottom surface of the first layer 72) using fasteners 76 or other suitable methods. Although FIG. 3B does not show the multi-layer reflector assembly 90 (see FIG. 3A), the guard ring 70B′ can be used in addition to or instead of it. Like the rim portion 70B in FIG. 2, guard ring 70B′ may surround substrate 30 to block sideways radiation. The cap 80′ can be adjusted vertically so the guard ring 70B′ bottom edge is close to, or touching, the carrier's top surface, creating a bounded volume around the substrate. The gap between the guard ring 70B′ bottom edge and the carrier top surface can be adjusted to be about 0-20 mm (or 0-10 mm).

In some implementations, as shown in FIG. 3C, includes an external multi-layer reflector assembly 90′ (with reflectors 90A and 90B) attached to its underside, similar to FIG. 3A, and an internal multi-layer reflector assembly 90″ (with reflectors 90C and 90D) positioned between the first and second layers 72 and 74. Both assemblies 90′ and 90″ can be secured using fasteners 76 or other suitable methods. These reflectors are designed to reflect radiant heat back to the substrate 30, with the internal assembly also enhancing the thermal barrier between the layers.

Referencing FIG. 1, the induction heater 50 is used for both heating and cooling the substrate 30 in various processing zones and steps. When the substrate is heated, the induction heater 50 actively heats it. Conversely, in cooling steps, the induction heater 50 is turned off, allowing it to absorb the radiated heat from the hot substrate, thus acting as a heat sink. This process cools the substrate quickly, aided by coolant flow through the induction heater 50. The coolant flow rate can be adjusted to achieve the desired cooling rate. Radiant heat from the substrate may also be absorbed and removed via the cap in a cooling zone since materials used as first and second layers 72, 74 (graphite, ceramics, etc.) of the cap are effective for absorbing radiant heat from the hot substrate. The coolant flow through the cap may also be adjusted to achieve a desired cooling rate of the substrate.

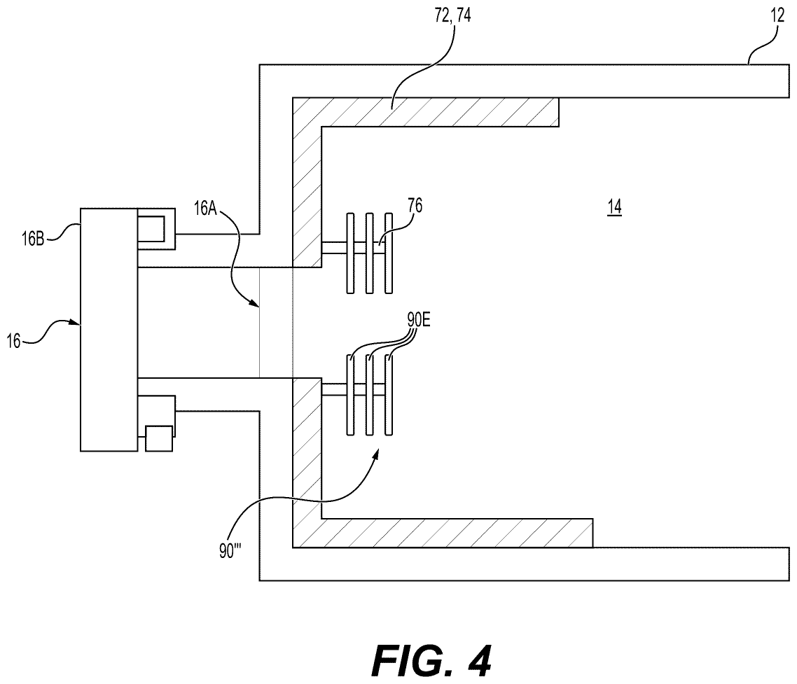

In addition to reflector assemblies coupled to the heat shield, reflector assemblies may also be positioned at other locations on the chamber 10. FIG. 4 illustrates an exemplary implementation where a reflector assembly 90′″ is coupled to the chamber wall around the port 16 through which substrate 30 is inserted and removed. Reflector assembly 90′″ may include multiple reflectors 90E similar to reflectors 90A-90D discussed previously. These reflectors may be coupled together using fasteners 76 (or by another suitable method). In some implementations (e.g., in a high-volume manufacturing environment), door 16B of port 16 may be a gate valve (e.g., with liquid cooling) that separates two zones—a low-temperature robotic handler chamber on the left size and the hot chamber volume 14 on the right side.

In implementations of the current disclosure, direct inductive heating (using a pancake-style coil induction heater in some implementations) is used to heat an individual substrate placed near the heater in a chamber. One or more heat shields are used to minimize thermal losses, improve temperature uniformity, and reduce wafer warping. The substrate is heated using an induction heater placed below the substrate. One heat shield is placed above the substrate and one heat shield is placed on the opposing side and below the induction heater to minimize losses to the ambient environment and chamber walls. Studies by the inventors have shown that annealing times for silicon carbide substrates can be reduced from hours to minutes by annealing at temperatures between 1800-1900° C. using the disclosed methods and tools. Single-substrate annealing using the disclosed systems and methods presents a superior and viable option for rapid annealing of silicon carbide substrates. It has faster throughput per wafer, exercises higher degree of control (vs large batches), allows “property freeze” due to rapid cooling, better uniformity control, better yield due to better control, and reduced contamination risk.

In some implementations described here, modular multi-stage heating and cooling processes are detailed. As seen in FIGS. 1A and 1B, these methods streamline the loading, heating, cooling, and unloading of the substrate 30 into the chamber 10 of an apparatus. Initially, substrate 30 is placed in loading/unloading zone of chamber 10, and then moved to a heating station, where it is heated by an induction heater 50, as illustrated in FIG. 2. As the substrate heats up, it emits heat proportional to T⁴, thereby acting as a powerful heater. Heat shields above and below the substrate reflect the emitted heat back to it, enhancing heating efficiency and protecting the chamber components. Heating can occur in a single step or multiple steps. After reaching the desired annealing temperature, the substrate is rotated through one or more cooling stations for radiative cooling before reaching the unloading station from where it is removed.

One challenge in high-volume production is handling substrates. A hot substrate will crack upon contact with a cold object (e.g., a robotic handler's arm). Thus, removing a substrate exceeding a thousand degrees Celsius from the chamber with a robotic arm before cooling will likely cause it to crack and break. By heating the silicon carbide substrate to annealing temperatures (exceeding 1500° C.) and quickly cooling it to a safe removal temperature before extraction, the disclosed systems and methods offer significant improvements over existing technology.

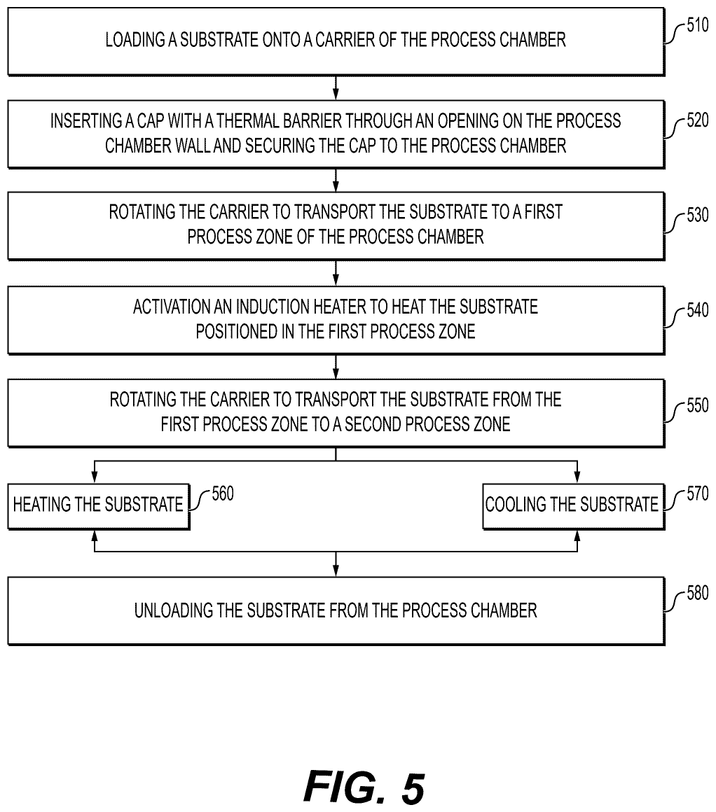

FIG. 5 is a flow chart of an exemplary method 500 of annealing a semiconductor substrate 30 using an exemplary disclosed apparatus. In the discussion below, reference will be made to FIGS. 1-4. The substrate 30 may be loaded on the carrier 20 of the process chamber 10 (step 510). As explained previously, carrier 20 may be configured to rotate about a vertical axis 120 to transport the substrate 30 through different zones (loading/unloading zone and multiple processing zones) of the process chamber 10, and in step 510, the substrate 30 may the loaded onto the carrier 20 in loading/unloading zone 40A. After loading the substrate 30, the carrier 20 may be rotated to sequentially transport the substrate through the different processing zones 40B, 40C, etc. In general, the substrate 30 may be heated or cooled at these processing zones using induction heaters 50.

The process chamber wall (e.g., top wall 12C) may include openings 18 (apertures, cutout, etc.) located above the different processing zones. An elongate cap 80 with coolant channels 82 at a first end and a heat shield 70 (with one or more thermal insulation layers 72, 74, etc.) coupled to a second end may be inserted into the process chamber 10 through these openings 80. When a cap 80 is inserted through an opening above a processing zone (e.g., first heating zone, second cooling zone, etc.), the heat shield 70 of the cap 80 will be located above the substrate 30 located in that processing zone. Typically, different caps 80 (e.g., caps with different configuration or types of heat shields 70) may be inserted into the wall openings 18 corresponding to the different processing zones. In some implementations, a cap 80 with a selected heat shield 70 may be inserted through the wall openings 18 corresponding to some processing zones (and secured), and blanks (e.g., a cap without a heat shield 70) may be secured to the openings 18 above some processing zones to cover these opening 18 (e.g., when that processing zone is not used in a process). Thus, in step 520, a cap 80 with a heat shield 70 may be inserted through an opening 18 in the process chamber wall 18C and secured to the process chamber 10 such that the heat shield 70 is positioned above the carrier 20 in a processing zone.

In step 530, the carrier 20 may be rotated to transport the substrate 30 to a processing zone (40B, 40C, etc.) of the process chamber 10. For example, after loading the substrate into the loading/unloading zone 40A, the carrier 20 may be rotated to move the substrate 30 to the first processing zone 40B (e.g., a first heating zone). As another example, after the substrate 30 is heated in the first processing zone 40B, the carrier 20 may again be rotated to move the substrate 30 to a second processing zone 40C (which may be a second heating zone or a cooling zone).

In step 540, the induction heater 50 is activated to heat the substrate 30 located in the processing zone. For example, when the substrate 30 is located in the first processing zone 40B, the induction heater 50 located below the carrier 20 in the first processing zone is activated to heat the substrate 30 positioned in the first processing zone. As explained previously, the carrier 20 may have a cavity 22 with a plurality of standoffs 24 arranged around the periphery (or perimeter) of the cavity 22, and the substrate 30 may rest on the standoffs 24 with its bottom surface located over the cavity 22 and vertically spaced apart from the top surface of the carrier 20. The induction heater 50 may be positioned below the cavity 22 such that the bottom surface of the substrate 30 is exposed to, and heated by, the induction heater 50. The substrate 30 may be heated to any desired temperature by the induction heater 50. For example, when the substrate 30 is a silicon carbide substrate, the substrate 30 may be heated to the annealing temperature (e.g., greater than about 1800° C.) of the substrate 30. In some implementations, the substrate 30 may only be heated to a temperature lower than the annealing temperature (e.g., 1000° C.) in the first processing zone, and then rotated to a second processing zone to further heat the substrate 30 to the annealing temperature.

After heating the substrate 30 in step 540, the carrier 20 may rotate the substrate 30 from the first processing zone to a second processing zone in step 550. A second induction heater 50 (similar to the induction heater in the first processing zone) may be positioned below the carrier 20 in the second processing zone. The substrate 30 may be heated or cooled in the second processing zone using this induction heater 50. In some implementations, the second induction heater 50 may be activated to further heat the substrate in step 560. For example, if the substrate 30 is heated to a temperature lower than the annealing temperature in step 540, the substrate may be further heated to the annealing temperature in step 560. In some implementations, in step 570, the second induction heater 50 may not be activated, and the heated substrate 30 may be cooled using the second induction heater 50 in the second processing zone. For example, the electrically deactivated second induction heater 50 may absorb radiant heat from the substrate 30 to cool the substrate in the second processing zone. The coolant circulating through the induction heater 50 may assist with this cooling.

The substrate 30 may thus be heated to its annealing temperature and cooled to a desired temperature (e.g., a temperature that is low enough for safe removal of the substrate from the process chamber) using method 500. After cooling the substrate 30, the carrier 20 may again be rotated to move the substrate 30 to the loading/unloading zone of the process chamber 10. In some implementations, the carrier may rotate the substrate 30 through multiple processing zones on its way to the loading/unloading zone. In some implementations, the substrate 30 may be heated or cooled in these processing zones. Typically, if a processing zone of the process chamber 10 is not used during a process, the wall opening 18 (through which the removable cap 80 is inserted into the process chamber 10) corresponding to that processing zone may be plugged (e.g., using a blank cap). In step 580, the substrate 30 may be removed from the process chamber 10.

It should be noted that the steps described with reference to FIG. 5, and the illustrated order of the steps, are merely exemplary. For example, the steps may be performed in a different order. For example, in some implementations, step 520 may be performed before step 510 or after step 530. Moreover, in some implementations, some of the steps may be eliminated and/or other steps added, ultimately reducing it to a single chamber operation.

Various modifications can be made to the implementations described above. In the above-described implementations, the induction heater 50 heats the substrate 30, which in turn transfers heat to the heat shield 70 (70′, 70″, etc.). However, in some applications, this passive heat transfer between the substrate and the heat shield can result in uncontrolled variations and non-uniform temperature distribution in the substrate during processing. To address this, some implementations incorporate active temperature control for the heat shield. Specifically, the heat shield's temperature can be actively regulated to achieve the desired uniformity across the substrate. For instance, the heat shield may feature one or more heating elements for active temperature control across different regions of the shield. In some cases, these heating elements may be coated with tantalum carbide for improved performance.

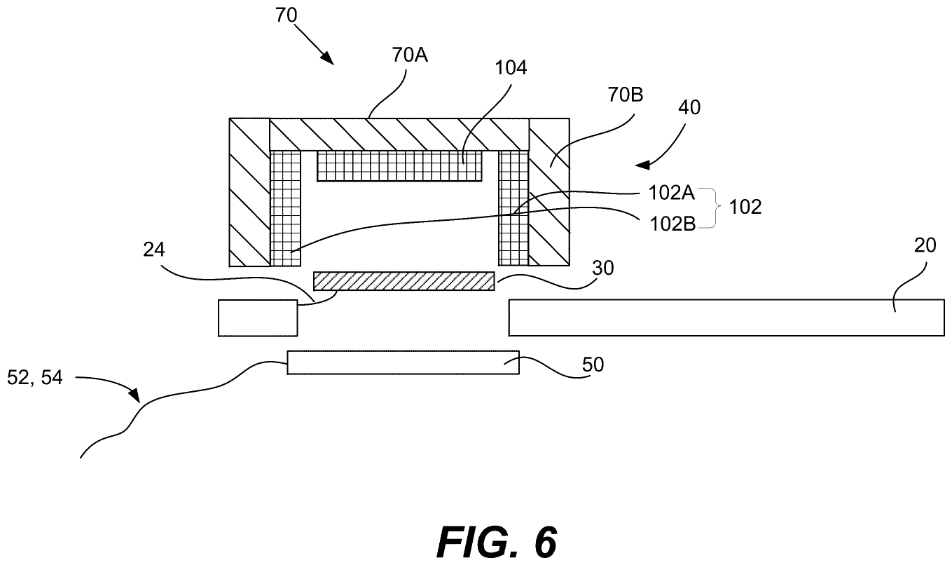

FIG. 6 is a schematic illustration of an implementation of active temperature control of the heat shield in the processing zone of the chamber of FIG. 1, consistent with some implementations of the current disclosure. In the system of FIG. 6, the shield temperature is actively regulated during processing of the substrate. As with the previous implementations, the processing of the substrate may be in region 40 of chamber 10 (of FIG. 1). For example, when chamber 10 has multiple zones, the region depicted in FIG. 6 may correspond to any processing zone (e.g., 40B, 40C, etc.) to which the carrier rotates the substrate 30 (see FIG. 1). And when chamber 10 has a single zone, the region depicted in FIG. 6 may correspond to that single zone (e.g., the location where the substrate is inserted and placed in the chamber). For the sake of brevity, the discussion below may exclude features of FIG. 6 that are shared with the previously described implementations.

As previously described, the substrate 30, supported by the carrier 20 on standoffs 24, is heated inductively by the induction heater 50. As previously described, electrical cables 52 direct current to the induction heater 50 and fluid conduits 54 circulate a liquid coolant to the induction heater 50. The surface of the heat shield 70 (or its thermal insulation layer) facing the substrate 30 is warmed by the substrate itself, as the heated substrate acts as a highly effective radiative heater. During the processing of the first wafer in zone 40, the heat shield 70 begins at a cold state and gradually reaches a quasi-steady state. For instance, as the carrier 20 rotates multiple substrates sequentially through zone 40, the shield 70 may exhibit one temperature while processing a specific substrate and a different temperature for subsequent substrates. Consequently, significant variations in the shield's temperature may occur from one substrate to another, potentially leading to inconsistencies in the temperature distribution across the substrate 30 being processed.

In some implementations, the heat shield 70 incorporates one or more heaters to actively regulate its temperature to alleviate this inconsistencies in the temperature distribution across the substrate 30. As depicted in FIG. 6, in some implementations, three resistive heaters—102A, 102B, and 104—are attached to the substrate-facing side of the heat shield 70. In implementations where the heat shield 70 has a hat-like shape (as shown in FIG. 6), heater 104 may be positioned on the inner, substrate-facing side of the crown portion 70A, while heaters 102A and 102B may be mounted inside the rim portion 70B, which extends downward from the periphery of the crown portion. In some cases, heaters 102A and 102B may be combined into a single heater 102. The heater 104 may be referred to as the inner heater, while the heaters 102A and 102B (or single heater 102) may be referred to as the outer heater(s). The number and configuration of the resistive heater for active temperature control of the heat shield 70 are not limited and can depend on the process requirement and the overall chamber design. In some implementations, one or more heaters can be installed only in the crown portion, in the rim portion, or both.

During the processing of substrate 30, the temperatures of the outer and inner heaters 102 and 104 can be actively controlled to ensure a uniform temperature distribution across all regions of the substrate 30 (or within a defined threshold of variation). Typically, during processing, the outer edge or periphery of the substrate 30 is cooler than its center. Therefore, in some implementations, the outer heaters 102 are maintained at higher temperatures than the inner heater 104. By activating the outer heater 102, the temperature gradient between the cooler outer regions of the substrate 30 and the heat shield 70 is reduced compared to the gradient at the hotter central region. This varying temperature gradient leads to greater heat transfer from the substrate 30 to the heat shield 70 at the center than at the edges, promoting a more uniform substrate temperature.

Thus, active temperature regulation of the heat shield 70 during substrate processing improves temperature uniformity across the substrate 30. In sone implementations, only the outer heater 102 may be activated, while the inner heater 104 remains inactive. The heaters 102 and 104 can be operated either at constant setpoint temperatures or with time-dependent thermal control. By employing controlled shield temperatures within the 900-1400° C. range, temporal and spatial variations in temperature of substrate 30 can be effectively reduced. However, maintaining multiple heaters 102, 104 at such elevated temperatures can introduce challenges, especially beyond 1200° C. In such scenarios, tantalum carbide-coated heating elements, which can operate at temperatures up to 2200° C., can be used as heaters 102, 104.

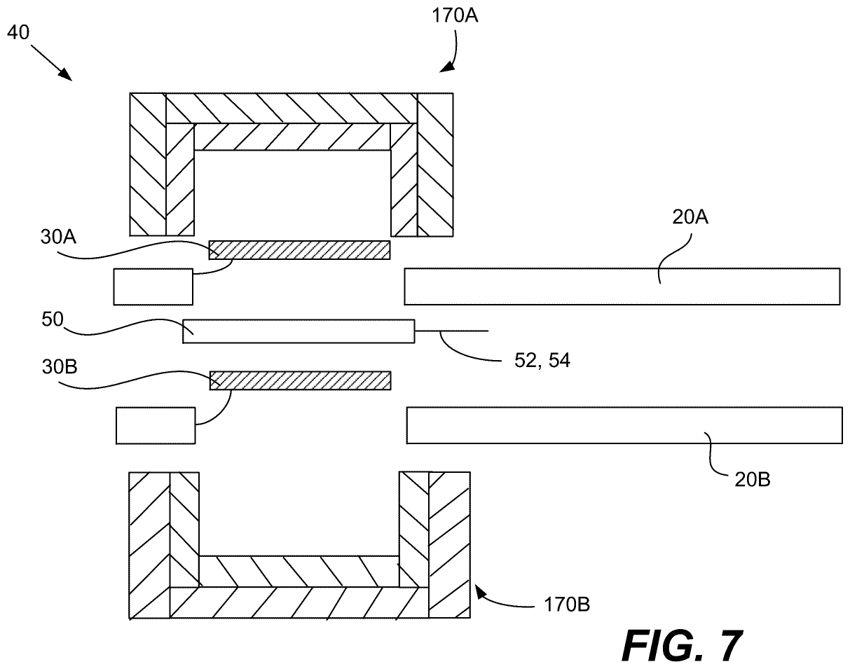

In the described implementations, a single wafer 30 is processed at a time within a designated zone of chamber 10, positioned above the induction heater 50. To improve throughput, the magnetic field generated by the induction heater 50 on two opposite sides (e.g., upper and lower sides) can be utilized to enable simultaneous processing of two substrates positioned above and below the heater. FIG. 7 provides a schematic illustration of an implementation where two substrates, 30A and 30B, are processed simultaneously within a zone 40 of chamber 10 (not shown). To compete successfully with existing batch processing methods, single-wafer processing would ideally complete heating, cooling, loading, and unloading within 3 about minutes in a single chamber (e.g., chamber 10). Processing multiple substrates simultaneously may assist in achieving this throughput.

As with the previous implementations, the processing of the substrate may be in any region 40 of chamber 10 (of FIG. 1). For the sake of brevity, the discussion below will exclude features of FIG. 7 that are shared with the previously described implementations. Substrate 30A is supported on carrier 20A positioned above the induction heater 50, as described earlier. Similarly, substrate 30B is supported on carrier 20B positioned below the induction heater 50. During operation, the induction heater 50 simultaneously heats both substrates, 30A and 30B. Carriers 20A and 20B may form parts of two carousel systems that rotate around a shared axis (axis 120) within chamber 10 (referenced in FIG. 1). As an alternative to independent carriers 20A and 20B, the two substrates may be supported in any manner and positioned on opposite sides of the induction heater 50.

To cool the two substrates 30A and 30B, a first heat shield 170A is positioned above substrate 30A, while a second heat shield 170B is placed below substrate 30B. During operation, heat shield 170A absorbs heat from and cools substrate 30A, while heat shield 170B performs the same functions for substrate 30B. Heat shields 170A and 170B may be similar in structure and may be symmetrically positioned on opposite sides of the substrates 30A, 30B. In some implementations, the first and/or second heat shields 170A, 170B may include heaters (as described with reference to FIG. 6) to actively control the temperature of different regions of the heat shields.

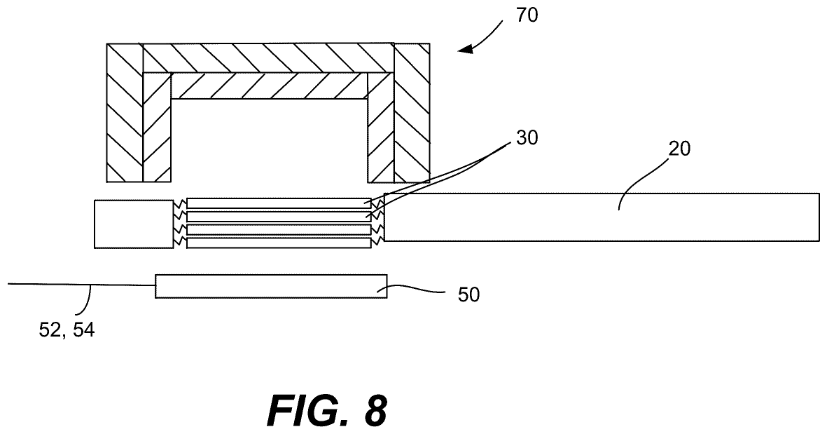

In some implementations, more than two substrates can be processed simultaneously in a single zone within chamber 10 (referenced in FIG. 1). As illustrated in FIG. 8, multiple substrates 30 (e.g., three, four, give or six substrates, among other suitable numbers of substrates) may be supported on a carrier 20 and positioned above an induction heater 50 for heating. A heat shield 70 may also be positioned above the substrates 30 to facilitate cooling. When powered, the induction heater 50 heats the multiple substrates 30 simultaneously. In implementations of the present disclosure, the induction heater 50 can be connected to a power supply with a capacity ranging from 10 kW to 250 kW. To achieve the same heating rate as that for a single substrate 30, the power supply in the implementation of FIG. 8 may need to be increased four-fold. For instance, in an exemplary implementation where the induction heater 50 heats a single substrate 30 within chamber 10, the induction heater 50 may be paired with a 25 kW power supply. In the implementation of FIG. 8, where four substrates are processed simultaneously, a power supply rated at 100 kW or higher may be used.

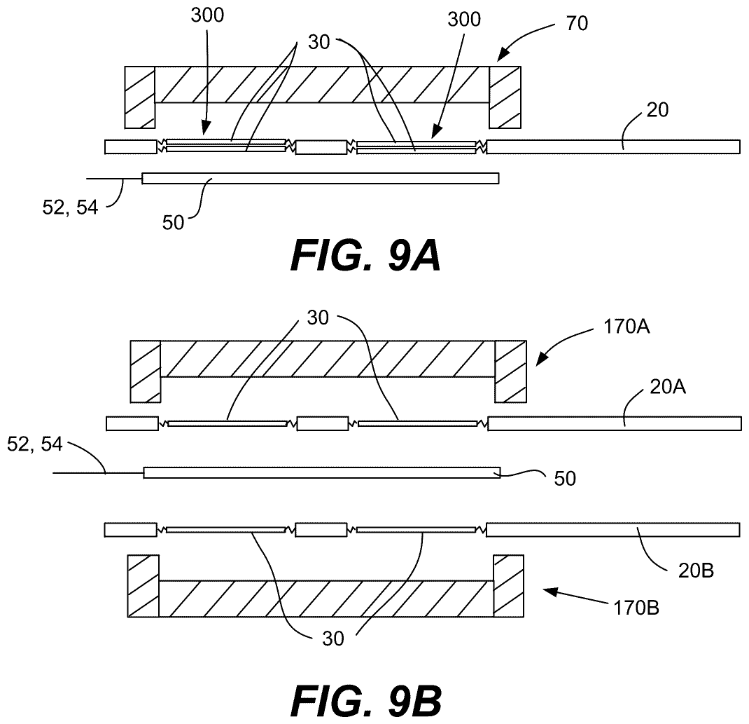

In some implementations, the power supply frequency may be increased to enable the simultaneous heating of multiple substrates. Raising the power supply frequency reduces the thickness of the magnetic coupling layer (skin effect), which also weakens the magnetic field outside this layer. Consequently, substrates 30 may be positioned closer to the induction heater 50 in such configurations. Conversely, using a lower-frequency power supply creates a broader magnetic field zone, allowing multiple substrates to be placed horizontally adjacent to one another, as depicted in the implementations of FIGS. 9A and 9B.

Low-frequency inductive heating and high-frequency inductive heating can differ in their depth of heat penetration and magnetic field behavior. Low-frequency heating, typically operating at frequencies from 50 Hz to a few kHz, generates a broader magnetic field that penetrates deeper into the material being heated. This reduced “skin effect” allows heat to distribute uniformly throughout thicker or larger objects. In contrast, high-frequency inductive heating, which operates at frequencies in the kHz to MHz range, produces a concentrated and shallow magnetic field.

In the implementation of FIG. 9A, a plurality of stacks 300 of multiple substrates 30 can be spaced horizontally and positioned above an induction heater 50 powered using a lower-frequency power supply. A heat shield 70 may extend over these horizontally spaced substrate stacks 300 to facilitate cooling. Although not depicted in FIG. 9A, other implementations may include a separate heat shield for each horizontally spaced substrate stacks 300. Furthermore, in some implementations, different induction heaters may be positioned beneath each of the stacks 300 to provide independent heating control.

In some implementations, as shown in FIG. 9B, two carriers, 20A and 20B, positioned on opposite sides of the induction heater 50, may support horizontally spaced substrates 30. A first heat shield 170A may be placed above the substrates 30 on carrier 20A, while a second heat shield 170B may be positioned below the substrates 30 on carrier 20B to facilitate cooling. In some configurations, as described with reference to FIG. 9A, a separate heat shield may be assigned to each horizontally spaced substrate.

In some implementations of the current disclosure, an annealing system for semiconductor substrates includes a process chamber with a central axis and multiple process zones arranged angularly around the axis. Among these zones are a first and a second process zone. A carrier, positioned within the chamber, is designed to support the substrate and rotate about the central axis, enabling the transportation of the substrate from the first process zone to the second. An induction heater is situated in the first process zone below the carrier and configured to heat the substrate during processing. Positioned above the substrate in the first process zone is a heat shield, which comprises at least one layer of thermally insulating material. The heat shield features a crown portion and a rim portion that extends around the periphery of the crown. To control the temperature distribution, a first resistive heater is coupled to the crown portion, and a second resistive heater is attached to the rim portion, allowing for temperature adjustments of the rim relative to the crown.

Different implementations of the above-described annealing system may include various features, either individually or in combination. The vertical distance between the substrate and the heat shield may be adjustable. The heat shield can be attached to a removable cap coupled to the process chamber, with the cap containing coolant channels designed to circulate liquid coolant. The heat shield may comprise multiple layers of thermally insulating materials, with at least one layer made from graphite or a high-temperature ceramic. Alternatively, the heat shield may include a single layer of thermally insulating material. In some configurations, the rim portion of the heat shield may extend downward from the crown portion's periphery, forming a cavity enclosed by the rim and crown. The substrate may be positioned at least partially within this cavity.

The carrier may feature a cavity bordered by multiple standoffs arranged around its perimeter, allowing the substrate to rest on the standoffs so that its bottom surface is suspended above the cavity and vertically separated from the carrier's top surface. Positioned below the carrier, the induction heater may face the substrate's bottom surface through the cavity. This induction heater may be a liquid-cooled pancake-style coil heater. Furthermore, the heat shield can be attached to a cap designed to be inserted into the process chamber via an opening in its wall and removably secured, ensuring the heat shield is positioned above the substrate.

In another implementation, an annealing system for semiconductor substrates includes a process chamber housing two carriers positioned within it. The first carrier includes a cavity designed to support a substrate such that the bottom surface of the substrate is exposed through the cavity. Similarly, the second carrier has a cavity configured to hold a second substrate, exposing its bottom surface through the cavity. Positioned between the two carriers is a liquid-cooled induction heater, located below the first carrier and above the second carrier. This arrangement allows the bottom surface of the first substrate, exposed through the cavity, to be heated from below, while the top surface of the second substrate is heated from above by the same induction heater. To manage thermal conditions, the system incorporates two heat shields: the first heat shield, comprising at least one layer of thermally insulating material, is located above the first carrier, ensuring the top surface of the first substrate is shielded and cooled by this heat shield; and the second heat shield, also made of thermally insulating material, is positioned below the second carrier to cover the bottom surface of the second substrate as it is exposed through the cavity.

Different implementations of the above-described annealing system may include additional or alternative features to enhance functionality. The first heat shield may be attached to a cap secured to the process chamber, allowing for an adjustable vertical distance between the heat shield and the first substrate. This cap may also contain coolant channels designed to circulate liquid coolant. The heat shield can include multiple layers of thermally insulating materials, with at least one layer made of graphite or a high-temperature ceramic. The first heat shield may include a crown portion and a rim portion extending around its periphery, with a first resistive heater coupled to the crown portion and a second resistive heater attached to the rim portion, enabling temperature adjustments of the rim relative to the crown. Similarly, the second heat shield may have a crown portion and a rim portion, with a third resistive heater connected to the crown and a fourth resistive heater linked to the rim to regulate the rim's temperature relative to the crown.

In some configurations, the first heat shield may feature a crown portion and a downward-extending rim portion that forms a cavity enclosed by the rim and crown. This heat shield can be positioned above the first carrier, with the first substrate partially located within the cavity. The first carrier itself may include a cavity surrounded by multiple standoffs arranged along its perimeter, allowing the first substrate to rest on these standoffs. This setup ensures that the bottom surface of the substrate is suspended above the cavity and vertically spaced apart from the carrier's top surface. Additionally, the induction heater used in the system may be a pancake-style coil induction heater, further optimizing the heating process.

Although in the description above, some features were described with reference to specific implementations, a person skilled in the art would recognize that this is only exemplary, and the features disclosed with reference to one implementation are applicable to all disclosed implementations. Further, although the current disclosure is described with reference to specific implementations, persons of ordinary skill in the art would recognize that many variations are possible and within the scope of this disclosure. Other implementations of the apparatus, its features and components, and related methods will be apparent to those skilled in the art from consideration of the disclosure herein.

What is claimed is:

1. An annealing system for a semiconductor substrate, comprising:
a process chamber having a central axis and multiple process zones angularly spaced apart from each other about the central axis, wherein the multiple process zones include a first process zone and a second process zone;
a carrier positioned in the process chamber, wherein the carrier is configured to support the substrate and rotate about the central axis to transport the substrate from the first process zone to the second process zone;
an induction heater located in the first processing zone of the process chamber, wherein the induction heater is positioned below the carrier and configured to heat the substrate positioned in the first process zone;
a heat shield including at least one layer of a thermally insulating material disposed above the substrate positioned in the first process zone, wherein the heat shield includes a crown portion and a rim portion extending around a periphery of the crown portion; and
a resistive heater coupled to the heat shield to vary a temperature of the rim portion relative to a temperature of the crown portion.

2. The annealing system of claim 1, wherein the resistive heater is a first resistive heater coupled to the crown portion of the heat shield, the system further comprising: at least one second resistive heater coupled to the rim portion of the heat shield.

3. The annealing system of claim 1, wherein the resistive heater is a first resistive heater coupled to the rim portion of the heat shield, the system further comprising:
at least one second resistive heater coupled to the crown portion of the heat shield.

4. The annealing system of claim 1, wherein the resistive heater comprises a tantalum carbide-coated heating element operable at temperatures between 1200° C. and 2200° C.

5. The annealing system of claim 1, wherein the heat shield is coupled to a cap that is removably coupled to the process chamber, wherein the cap includes coolant channels configured to circulate a liquid coolant therethrough.

6. The annealing system of claim 1, wherein the heat shield includes multiple layers of thermally insulating materials and at least one of the multiple layers includes graphite or a high temperature ceramic.

7. The annealing system of claim 1, wherein the heat shield includes a single layer of the thermally insulating material.

8. The annealing system of claim 1, wherein the rim portion of the heat shield extends downwards from the periphery of the crown portion to define a cavity bounded by outer walls of the rim portion and the crown portion, and wherein the heat shield is disposed above the substrate such that the substrate is disposed at least partially within the cavity.

9. The annealing system of claim 1, wherein the carrier includes a cavity with a plurality of standoffs arranged around a periphery of the cavity, and wherein the substrate is configured to rest on the plurality of standoffs such that a bottom surface of the substrate is positioned over the cavity and vertically spaced apart from a top surface of the carrier.

10. The annealing system of claim 1, wherein the heat shield is coupled to a cap configured to be inserted into the process chamber through an opening on a wall of the process chamber and removably secured to the process chamber such that the heat shield is disposed above the substrate.

11. An annealing system for semiconductor substrates, comprising:
a process chamber;
a first carrier positioned in the process chamber, wherein the first carrier includes a first cavity configured to support a first substrate such that a bottom surface of the first substrate is exposed through the first cavity;
a second carrier positioned in the process chamber, wherein the second carrier includes a second cavity configured to support a second substrate such that a bottom surface of the second substrate is exposed through the second cavity;
an induction heater disposed below the first carrier and above the second carrier such that the bottom surface of the first substrate that is exposed through the first cavity is positioned above the induction heater and a top surface of the second substrate is positioned below the induction heater;
a first heat shield including at least one layer of a thermally insulating material disposed above the first carrier such that a top surface of the first substrate is positioned below the first heat shield; and
a second heat shield including at least one layer of a thermally insulating material disposed below the second carrier such that the bottom surface of the second substrate exposed through the second cavity is positioned above the second heat shield.

12. The annealing system of claim 11, wherein the first heat shield is coupled to a cap secured to the process chamber such that a vertical distance between the first heat shield and the first substrate is adjustable.

13. The annealing system of claim 12, wherein the cap includes coolant channels configured to circulate a liquid coolant thereto.

14. The annealing system of claim 11, wherein the heat shield includes multiple layers of thermally insulating materials.

15. The annealing system of claim 14, wherein at least one of the multiple layers includes graphite or a high temperature ceramic.

16. The annealing system of claim 11, wherein the first heat shield includes a first crown portion and a first rim portion extending around a periphery of the first crown portion, and wherein a first resistive heater is coupled to the first crown portion and a second resistive heater is coupled to the second rim portion to vary a temperature of the first rim portion relative to the first crown portion.

17. The annealing system of claim 16, wherein the second heat shield includes a second crown portion and a second rim portion extending around a periphery of the second crown portion, and wherein a third resistive heater is coupled to the second crown portion and a fourth resistive heater is coupled to the second rim portion to vary a temperature of the second rim portion relative to the second crown portion.

18. The annealing system of claim 11, wherein the first heat shield includes a first crown portion and a first rim portion extending downwards from a periphery of the first crown portion to define a cavity bounded by outer walls of the first rim portion and the first crown portion, and wherein the first heat shield is disposed above the first carrier such that the first substrate is disposed at least partially within the cavity.

19. The annealing system of claim 11, wherein the first carrier includes a plurality of first standoffs arranged around a periphery of the first cavity, and wherein the first substrate is configured to rest on the plurality of first standoffs such that the bottom surface of the first substrate is positioned over the first cavity and vertically spaced apart from a top surface of the first carrier.

20. An annealing system for a semiconductor substrate, comprising:
a process chamber having a central axis and multiple process zones angularly spaced apart from each other about the central axis, wherein the multiple process zones include a first process zone and a second process zone;
a carrier positioned in the process chamber, wherein the carrier is configured to (i) support a vertical stack of a plurality of substrates and (ii) rotate about the central axis to transport the vertical stack from the first process zone to the second process zone;
an induction heater located in the first process zone of the process chamber, wherein the induction heater is positioned below the carrier and configured to heat the substrate positioned in the first process zone; and
a heat shield including at least one layer of a thermally insulating material disposed above the substrate positioned in the first process zone, wherein the heat shield includes a crown portion and a rim portion extending around a periphery of the crown portion.

21. The annealing system of claim 20, wherein the carrier is further configured to support a plurality of horizontally spaced substrates, and the heat shield extends to cover the plurality of horizontally spaced substrates.

22. The annealing system of claim 20, further comprising:
a first resistive heater coupled to the crown portion of the heat shield; and
a second resistive heater coupled to the rim portion of the heat shield.
